(19) United States
(12) Patent Application Publication
(10) Pub. No.: US 2011/0284815 A1
(43) Pub. Date: Nov. 24, 2011

(54) PHASE-CHANGE MEMORY DEVICES HAVING STRESS RELIEF BUFFERS

(75) Inventors: Ik-soo Kim, Yongin-si (KR); Soon-oh Park, Suwon-si (KR); Dong-ho Ahn, Hwaseong-si (KR); Sung-lae Cho, Gwacheon-si (KR); Dae-hong Ko, Goyang-si (KR); Hyun-chul Sohn, Seoul (KR); Ki-hoon Do, Seoul (KR); Mann-ho Cho, Seoul (KR)

(73) Assignee: Samsung Electronics Co., Ltd.

(21) Appl. No.: 13/070,648

(22) Filed: Mar. 24, 2011

(30) Foreign Application Priority Data
May 24, 2010 (KR) 10-2010-0048192

(51) Int. Cl. H01L 47/00

(52) U.S. Cl. 257/4; 257/E47.001

(57) ABSTRACT

A memory device includes a substrate and a memory cell including a first electrode on the substrate, a phase-change material region on the first electrode and a second electrode on the phase-change material region opposite the first electrode. The memory device further includes a stress relief buffer adjacent a sidewall of the phase-change material region between the first and second electrodes. In some embodiments, the stress relief buffer includes a stress relief region contacting the sidewall of the phase-change material region. In further embodiments, the stress relief buffer includes a void adjacent the sidewall of the phase-change material region.

### CROSS-REFERENCE TO RELATED APPLICATIONS

This application claims the benefit of Korean Patent Application No. 10-2010-0048192, filed on May 24, 2010, in the Korean Intellectual Property Office, the disclosure of which is incorporated herein in its entirety by reference.

### BACKGROUND OF THE INVENTION

The inventive subject matter relates to memory devices and, more particularly, to phase-change memory devices.

There is an ongoing demand for decreasing the size of electronic devices and for increasing the amount of data they can process. This has lead to a demand for increased operating speed and degree of integration of non-volatile memory devices used in such electronic devices. One type of non-volatile memory is the phase-change random access memory (PRAM), which uses a phase-change material for data storage. The volume of phase-change material region used in such a device may change as the state of the phase-change material region changes between a crystalline state and an amorphous state.

### SUMMARY OF THE INVENTION

In some embodiments of the inventive subject matter, a memory device includes a substrate and a memory cell including a first electrode on the substrate, a phase-change material region on the first electrode and a second electrode on the phase-change material region opposite the first electrode. The memory device further includes a stress relief buffer adjacent a sidewall of the phase-change material region between the first and second electrodes. In some embodiments, the stress relief buffer includes a stress relief region contacting the sidewall of the phase-change material region. In further embodiments, the stress relief buffer includes a void adjacent the sidewall of the phase-change material region.

According to some embodiments, the memory device includes an insulating layer disposed between the first and second electrodes and contacting the sidewall of the phase-change material layer. The stress relief buffer may include a stress relief layer disposed on the insulating layer. In further embodiments, the stress relief buffer may include a plurality of stress relief layers interleaved with a plurality of insulating layers between the first and second electrodes.

According to additional embodiments, the memory device includes an insulating layer disposed between the first and second electrodes and the stress relief buffer is disposed between a sidewall of the insulating layer and the sidewall of the phase-change material region. In some embodiments, the stress relief buffer may include a stress relief region disposed between the sidewall of the insulating layer and the sidewall of the phase-change material region. In further embodiments, the stress relief buffer may include a void between the sidewall of the insulating layer and the sidewall of the phase-change material region.

In additional embodiments, the memory device includes a plurality of memory cells, each including a first electrode on the substrate, a phase-change material region on the first electrode and a second electrode on the phase-change material region opposite the first electrode. The stress relief buffer may include a stress relief layer contacting sidewalls of the phase-change material layers of the plurality of memory cells. In further embodiments, the stress relief buffer may include respective stress relief regions adjacent sidewalls of the phase-change material layers of respective ones of the plurality of memory cells.

According to an aspect of the inventive subject matter, there is provided a non-volatile memory device including: a first electrode; a phase-change material region disposed on the first electrode; a stress relief layer disposed to surround at least a part of the phase-change material region and relieving a stress of the phase-change material region; and an second electrode disposed on the phase-change material region.

In some embodiments of the inventive subject matter, the stress relief layer may surround a lower portion of the phase-change material region.

In some embodiments of the inventive subject matter, the non-volatile memory device may further include a lower insulating layer contacting a sidewall of the stress relief layer opposite the phase-change material region. An uppermost surface of the stress relief layer and an uppermost surface of the lower insulating layer may be coplanar. The non-volatile memory device may further include an upper insulating layer disposed on the lower insulating layer and the stress relief layer. The lower insulating layer and the upper insulating layer may have etch selectivity with respect to each other.

In some embodiments of the inventive subject matter, the stress relief layer may cover an entire side of the phase-change material region.

In some embodiments of the inventive subject matter, the stress relief layer may cover an entire side of the phase-change material region. The non-volatile memory device may further include a lower insulating layer contacting a sidewall of the stress relief layer opposite the phase-change material region.

In some embodiments of the inventive subject matter, the phase-change material region may be buried in the stress relief layer.

In some embodiments of the inventive subject matter, the stress relief layer may be included in a complex layer. The stress relief layer and the upper insulating layer may be alternately stacked on each other in the complex layer.

In some embodiments of the inventive subject matter, the stress relief layer may have a separated shape to surround the phase-change material region.

In some embodiments of the inventive subject matter, the stress relief layer may be a continuous layer surrounding the phase-change material region.

In some embodiments of the inventive subject matter, the phase-change material region may have a line shape extending to a first direction.

In some embodiments of the inventive subject matter, the phase-change material region may have an individually separated shape according to a node.

In some embodiments of the inventive subject matter, the first electrode and the phase-change material region may have the same width.

In some embodiments of the inventive subject matter, the stress relief layer may include a low dielectric material.

In some embodiments of the inventive subject matter, the stress relief layer may include at least one selected from the group consisting of silicon carbonitride (SiCN), boron carbonitride (BCN), and boron nitride (BN).

In some embodiments of the inventive subject matter, the phase-change material region may include a chalcogenide material.

According to an aspect of the inventive subject matter, there is provided a non-volatile memory device including: a first electrode; a phase-change material region disposed on the first electrode; a stress relief layer disposed to surround at least a part of the phase-change material region and including an air gap for relieving a stress of the phase-change material region; a lower insulating layer disposed on the stress relief layer; and an second electrode disposed on the phase-change material region.

According to an aspect of the inventive subject matter, there is provided a non-volatile memory device including: a first electrode; a phase-change material region disposed on the first electrode; a stress relief layer disposed adjacent the phase-change material region and relieving a stress of the phase-change material region; and a second electrode disposed on the phase-change material region.

According to another aspect of the inventive subject matter, there is provided a memory card including a non-volatile memory device, the memory card including: a memory including the non-volatile memory device including the phase-change material region; and a controller for controlling the memory and receiving and transmitting data with the memory.

According to another aspect of the inventive subject matter, there is provided a memory system including a non-volatile memory device, the memory system including: a memory including the non-volatile memory device including the phase-change material region; a processor communicating with the memory through a bus; and an input and output device communicating with the bus.

### BRIEF DESCRIPTION OF THE DRAWINGS

Exemplary embodiments of the inventive subject matter will be more clearly understood from the following detailed description taken in conjunction with the accompanying drawings in which:

FIG. 1 is a schematic diagram illustrating a non-volatile memory array according to some embodiments of the inventive subject matter;

FIG. 2 is a graph for describing a operations for set or reset programming on a phase-change material region included in a memory device;

FIG. 3 is a cross-sectional view illustrating a non-volatile memory device having a phase-change material, according to some embodiments of the inventive subject matter;

FIGS. 4 through 10 are cross-sectional views illustrating phase-change memory devices according to some embodiments of the inventive subject matter;

FIG. 11 is a plan view taken along a line I-I′ of FIG. 3;

FIG. 12 is a plan view taken along a line II-II′ of FIG. 9;

FIGS. 13A through 13E are cross-sectional views illustrating operations for forming a stress relief and a phase-change material region of FIG. 3;

FIGS. 14A through 14E are cross-sectional views for describing a operations for forming a stress relief and a phase-change material region of FIG. 9;

FIG. 15 is a schematic diagram illustrating a card according to some embodiments of the inventive subject matter; and

FIG. 16 is a schematic diagram illustrating a system according to some embodiments of the inventive subject matter.

### DETAILED DESCRIPTION

Reference will now be made in detail to exemplary embodiments, examples of which are illustrated in the accompanying drawings. However, exemplary embodiments are not limited to the embodiments illustrated hereinafter, and the embodiments herein are rather introduced to provide easy and complete understanding of the scope and spirit of exemplary embodiments. In the drawings, the thicknesses of layers and regions are exaggerated for clarity.

It will be understood that when an element, such as a layer, a region, or a substrate, is referred to as being “on,” “connected to” or “coupled to” another element, it may be directly on, connected or coupled to the other element or intervening elements may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of exemplary embodiments.

Spatially relative terms, such as “above,” “upper,” “beneath,” “below,” “lower.” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “above” may encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of exemplary embodiments. As used herein, the singular forms “a,” “an” and “the” are intended to include the plural forms as well, unless the context clearly indicates otherwise. It will be further understood that the terms “comprises” and/or “comprising” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but may be to include deviations in shapes that result, for example, from manufacturing. For example, an implanted region illustrated as a rectangle may, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes may be not intended to illustrate the actual shape of a region of a device and are not intended to limit the scope of exemplary embodiments.

Unless otherwise defined, all terms (including technical and scientific terms) used herein have the same meaning as commonly understood by one of ordinary skill in the art to which exemplary embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

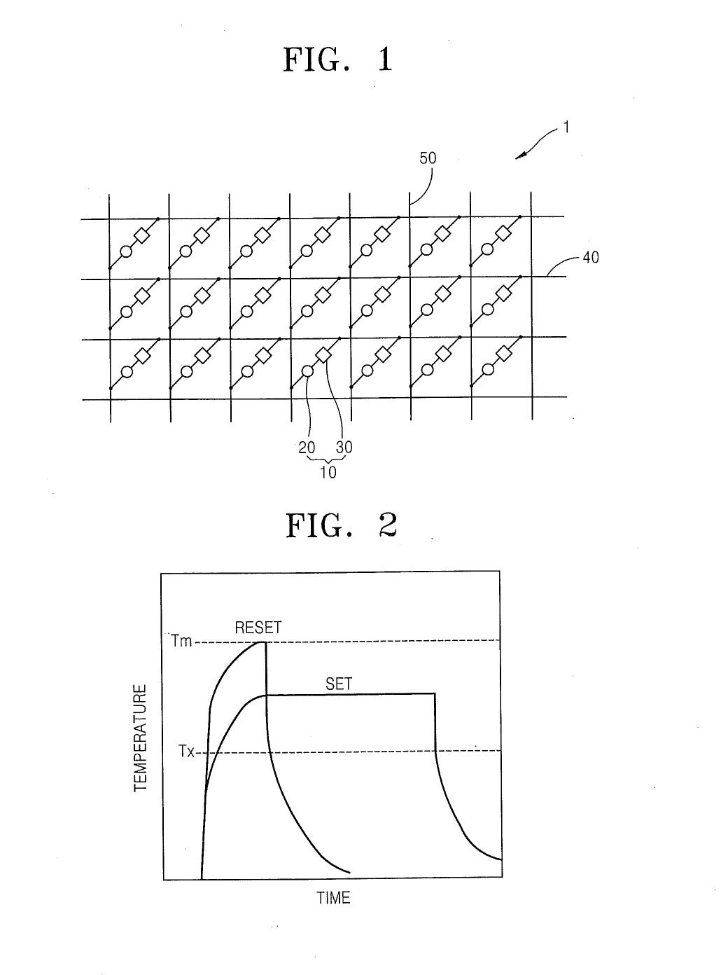

FIG. 1 is a schematic diagram illustrating a non-volatile memory array 1 according to some embodiments of the inventive subject matter.

Referring to FIG. 1, the non-volatile memory array 1 includes a plurality of memory device unit cells 10 arranged in a matrix. Each of the memory device unit cells 10 includes a memory portion 20 and an access portion 30. The memory device unit cell 10 is electrically connected to a first address line 40 and a second address line 50. The first address line 40 and the second address line 50 are 2-dimensionally arranged at a predetermined angle with respect to each other. The predetermined angle may be 90°, but is not limited thereto. One of the first address line 40 and the second address line 50 may be electrically connected to a bit line and the other may be electrically connected to a word line.

The memory portion 20 may include, for example, a phase-change material, a ferroelectric material, or a magnetic material. A state of the memory portion 20 may be determined according to an amount of current supplied to the memory portion 20 through the bit line.

The access portion 30 controls the current supplied to the memory portion 20 according to a voltage of the word line. The access portion 30 may be, for example, a diode, a bipolar transistor, or a metal oxide semiconductor (MOS) transistor.

In some embodiments below, a phase-change random access memory (PRAM) having a phase-change material is described as an example of a memory device of the memory portion 20. However, the memory device may use other memory storage media, i.e., the memory device may be a resistance RAM (RRAM), a ferroelectric RAM (FRAM), or a magnetic RAM (MRAM).

FIG. 2 is a graph illustrating operations for set or reset programming on a phase-change material region included in a memory device.

Referring to FIG. 2, when the phase-change material region is heated for a predetermined time at a temperature between a crystallization temperature Tx and a melting point Tm and then slowly cooled down, the phase-change material region changes to a crystallized state. The crystallized state may be referred to as a “set” state, wherein data “0” is stored in the phase-change material region. Alternatively, when the phase-change material region is heated up to a temperature equal to or above the melting point Tm and then quickly cooled down, the phase-change material region changes to an amorphous state. The amorphous state is referred to as a “reset” state, wherein data “1” is stored in the phase-change material region. Data may be stored in the phase-change material region by supplying a current, and data may be read from the phase-change material region by measuring a resistance value of the phase-change material region.

The heating temperature of the phase-change material region is proportional to an amount of current, and it is difficult to achieve high integrity as the amount of current increases. Typically, a greater amount of current is required to change the phase-change material region to the amorphous state (reset state) than to the crystallized state (set state). In order to reduce the power consumption, it is desirable to change the phase-change material region from the crystallized state to the amorphous state by heating the phase-change material using a relatively low amount of current. Specifically, in order to achieve high integrity, it is desirable to reduce reset current for changing the phase-change material region to the amorphous state.

A phase-change non-volatile memory device generally has a plurality of unit cells, each including an access portion and a memory portion, wherein the memory portion includes a phase-change material region. The phase-change material region is typically disposed between a lower electrode and an upper electrode, and the access portion typically is electrically connected to the lower electrode. Heating of the phase-change material region at a temperature between a crystallization temperature and a melting temperature or at a temperature equal to or above the melting point is performed according to an amount of write current flowing through the lower electrode and the access portion. In other words, when the write current flows through the lower electrode and the access portion, Joule heating occurs at an interface between the lower electrode and the phase-change material region, and a temperature achieved by the Joule heating is dependent on the amount of the write current.

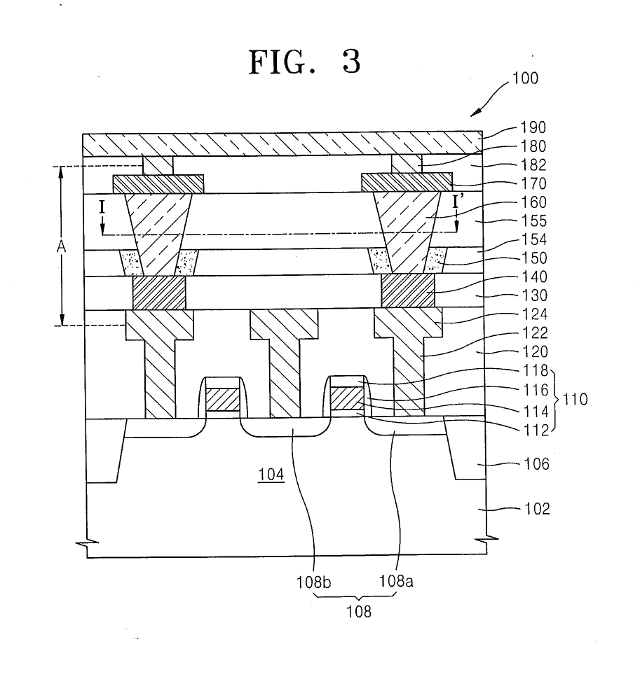

FIG. 3 is a cross-sectional view illustrating a phase-change non-volatile memory device 100 according to some embodiments of the inventive subject matter.

Referring to FIG. 3, the non-volatile memory device 100 includes a substrate 102, a gate structure 110 formed on the substrate 102 between impurity regions 108, a lower electrode 140, a phase-change material region 160, and an upper electrode 170. A portion of the device 100 corresponding to the memory portion 20 of FIG. 1 includes the lower electrode 140, the phase-change material region 160, and the upper electrode 170. A portion corresponding to the access portion 30 may include the gate structure 110 and impurity regions 108.

The substrate 102 includes a device isolation layer 106 that defines an active region 104. The substrate 102 may include a dielectric layer including a silicon oxide, a titanium oxide, an aluminum oxide, a zirconium oxide, or a hafnium oxide, a conductive layer including titanium (Ti), titanium nitride (TiN), aluminum (Al), tantalum (Ta), Tantalum nitride (TaN), and/or titanium aluminum nitride (TiAlN), or a semiconductor layer formed of silicon (Si), silicon-germanium (SiGe), and/or silicon carbide (SiC). The substrate 102 may include an epitaxial layer, a silicon-on-insulator (SOI) layer, and/or a semiconductor-on-insulator (SEOI) layer. Although not illustrated, the substrate 102 may further include a word line, a bit line, or other semiconductor devices. The device isolation layer 106 may be formed by using a shallow trench isolation (STI) process.

The impurity region 108 in the active region 104 may further include a low concentration impurity region adjacent the gate structure 110 and a high concentration impurity region spaced apart from the gate structure 110. The impurity region 108 may operate as a source/drain region, and for example, may include a source region 108a and a drain region 108b. The gate structure 110 is disposed on the active region 104 of the substrate 102. The gate structure 110 includes a gate insulating layer 112, a gate electrode layer 114, a spacer 116, and a capping layer 118. The gate structure 110, the source region 108a, and the drain region 108b may form a MOS transistor that operates as an access device. However, the formed structure may also be a diode or a bipolar transistor.

A first interlayer insulating layer 120 covers the gate structure 110 on the substrate 102. The first interlayer insulating layer 120 may include, for example, at least one of a silicon oxide, a silicon nitride, and a silicon oxynitride. A first contact plug 122 passes through the first interlayer insulating layer 120 and electrically contacts the source region 108a, and similar contact plug 122 passes through the first interlayer insulating layer 120 and electrically contacts the drain region 108b.

As illustrated in FIG. 3, the first contact plug 122 may include an expanded region 124 thereon, and the expanded region 124 may increase an electrical contact between the first contact plug 122 and the lower electrode 140. The first contact plug 122 may include, for example, at least one of titanium (Ti), titanium nitride (TiN), tungsten (W), and tungsten nitride (WN), or a stacked structure thereof. The first contact plug 122 may be a single layer including any one material thereof, a single layer including a plurality of materials thereof, a multilayer each layer including a single material thereof, and/or a multilayer each layer including a plurality of materials thereof.

A second interlayer insulating layer 130 is disposed on the first interlayer insulating layer 120. The second interlayer insulating layer 130 may include, for example, at least one of a silicon oxide, a silicon nitride, and a silicon oxynitride.

The lower electrode 140 is disposed in the second interlayer insulating layer 130. The lower electrode 140 is disposed on and electrically connected to the first contact plug 122. Accordingly, the lower electrode 140 is electrically connected to the gate structure 110 through the first contact plug 122 and the drain region 108b. The lower electrode 140 and the first contact plug 122 may be formed as a unitary structure. The lower electrode 140 may be formed by using an etching process, a damascene process, or a dual damascene process. The lower electrode 140 may include a metal such as aluminum (Al), copper (Cu), tungsten (W), titanium (Ti), or tantalum (Ta), an alloy such as titanium tungsten (TiW) or titanium aluminum (TiAl), or carbon (C). The lower electrode 140 may include titanium nitride (TiN), titanium aluminum nitride (TiAlN), tantalum nitride (TaN), tungsten nitride (WN), molybdenum nitride (MoN), niobium nitride (NbN), titanium silicon nitride (TiSiN), titanium boron nitride (TiBN), zirconium silicon nitride (ZrSiN), tungsten silicon nitride (WSiN), tungsten boron nitride (WBN), zirconium aluminum nitride (ZrAlN), molybdenum aluminum nitride (MoAlN), tantalum silicon nitride (TaSiN), tantalum aluminum nitride (TaAlN), titanium oxynitride (TiON), titanium aluminum oxynitride (TiAlON), tungsten oxynitride (WON), tantalum oxynitride (TaON), titanium carbonitride (TiCN), or tantalum carbonitride (TaCN).

The lower electrode 140 may be a single layer including any one material thereof, a single layer including a plurality of materials thereof, a multilayer each layer including a single material thereof, and/or a multilayer each layer including a plurality of materials thereof. The lower electrode 140 may have a shape of an extended line or an array of a plurality of polyhedrons. Alternatively, the lower electrode 140 may have a ring shape filled with a material different from the lower electrode 140, for example, with an insulator.

Although not illustrated, an etch stop layer may be optionally disposed on the lower electrode 140. The etch stop layer may include, for example, silicon oxynitride (SiON), hafnium oxide (HfO), or aluminum oxide (Al₂O₃). The etch stop layer may prevent the lower electrode 140 from being damaged in a following process.

The phase-change material region 160 is disposed on and electrically connected to the lower electrode 140. The phase-change material region 160 may be formed by using a sputtering process, a chemical vapor deposition (CVD) process, a plasma enhanced CVD (PECVD) process, or an atomic layer deposition (ALD) process. Although not illustrated, the non-volatile memory device 100 may further include a seed layer between the lower electrode 140 and the phase-change material region 160, wherein the seed layer enables the phase-change material region 160 to be more easily formed. The phase-change material region 160 may include a phase-change material, such as a chalcogenide material, for storing data according to different crystallized states as described above, for example, may include at least one of Ge—Te, Ge—Sb—Te, Ge—Te—Se, Ge—Te—As, Ge—Te—Sn, Ge—Te—Ti, Ge—Bi—Te, Ge—Sn—Sb—Te, Ge—Sb—Se—Te, Ge—Sb—Te—S, Ge—Te—Sn—O, Ge—Te—Sn—Au, Ge—Te—Sn—Pd, Sb—Te, Se—Te—Sn, Sb—Se—Bi, In—Se, and In—Sb—Te. The phase-change material region 160 may further include a metal. The phase-change material region 160 may be doped with at least one of carbon (C), nitrogen (N), silicon (Si), oxygen (O), bismuth (Bi), and tin (Sn), and a driving current of the non-volatile memory device 100 may be decreased according to such doping.

The phase-change material region 160 may be surrounded by a lower insulating layer 154 and an upper insulating layer 155, which are sequentially disposed on the second interlayer insulating layer 130. The lower insulating layer 154 and the upper insulating layer 155 may include an oxide, a nitride, or an oxynitride, and for example, may include at least one of a silicon oxide, a silicon nitride, and a silicon oxynitride. The lower insulating layer 154 and the upper insulating layer 155 may have an etch selectivity with each other. For example, the lower insulating layer 154 may include a silicon oxide, and the upper insulating layer 155 may include a silicon nitride. The lower insulating layer 154 and the second interlayer insulating layer 130 may have an etch selectivity with respect to each other.

At least a part, for example, a lower portion, of the phase-change material region 160 may be surrounded by a stress relief buffer 150, which, as explained in detail below, may be a stress relief region (e.g., a layer or a patterned region) or a void adjacent the phase-change material region 160. The lower insulating layer 154 may contact a sidewall of the stress relief buffer 150 opposite the phase-change material region 160. The stress relief buffer 150 may surround a region, such as a memory region or a switching region, of the phase-change material region 160 where state changes occur. Separate stress relief buffers 150 may surround each phase-change material region 160. At least a part, for example, an upper portion, of the phase-change material region 160 may be surrounded by the upper insulating layer 155.

The stress relief buffer 150 may include a material region having a lower modulus of elasticity than the lower insulating layer 154 and/or the upper insulating layer 155. The stress relief buffer 150 may include a low dielectric material, and for example, may include SiCN, BCN, and/or BN. Generally, the low dielectric material has a lower modulus of elasticity than a silicon oxide or a silicon nitride. Such a stress relief buffer 150 absorbs a stress energy generated due to a crystallized state change of the phase-change material region 160, and accordingly, may prevent deterioration of the phase-change material region 160. In the illustrated embodiments, the stress relief buffer 150 may be disposed between the lower insulating layer 154 and the phase-change material region 160. An uppermost surface of the stress relief buffer 150 and an uppermost surface of the lower insulating layer 154 may be coplanar. The shape of the stress relief buffer 150 shown in FIG. 3 is an example, and embodiments of the inventive subject matter are not limited thereto.

The upper electrode 170 is disposed on and electrically connected to the phase-change material region 160. The upper electrode 170 may include a metal such as aluminum (Al), copper (Cu), tungsten (W), titanium (Ti), tantalum (Ta), an alloy such as titanium tungsten (TiW), titanium aluminum (TiAl), or carbon (C). The upper electrode 170 may include titanium nitride (TiN), titanium aluminum nitride (TiAlN), tantalum nitride (TaN), tungsten nitride (WN), molybdenum nitride (MoN), niobium nitride (NbN), titanium silicon nitride (TiSiN), titanium boron nitride (TiBN), zirconium silicon nitride (ZrSiN), tungsten silicon nitride (WSiN), tungsten boron nitride (WBN), zirconium aluminum nitride (ZrAlN), molybdenum aluminum nitride (MoAlN), tantalum silicon nitride (TaSiN), tantalum aluminum nitride (TaAlN), titanium oxynitride (TiON), titanium aluminum oxynitride (TiAlON), tungsten oxynitride (WON), tantalum oxynitride (TaON), titanium carbonitride (TiCN), or tantalum carbonitride (TaCN). The upper electrode 170 may be a single layer including any one material from the above materials, a single layer including a plurality of materials from the above materials, a multilayer each layer including a single material from the above materials, and/or a multilayer each layer including a plurality of materials from the above. The lower electrode 140 and the upper electrode 170 may be formed of the same material or different materials.

A second contact plug 180 is disposed on and electrically connected to the upper electrode 170. The second contact plug 180 may include at least one of titanium (Ti), titanium nitride (TiN), tungsten (W), and tungsten nitride (WN), or may include a stacked structure thereof. The second contact plug 180 may be a single layer including any one material thereof, a single layer including a plurality of materials thereof, a multilayer each layer including a single material thereof, and/or a multilayer each layer including a plurality of materials thereof. The upper electrode 170 and the second contact plug 180 may be formed as a unitary structure. The upper electrode 170 and the second contact plug 180 may be surrounded by a third interlayer insulating layer 182. The third interlayer insulating layer 182 may include an oxide, a nitride, or an oxynitride. An upper wiring 190 may be disposed on and electrically connected to the second contact plug 180.

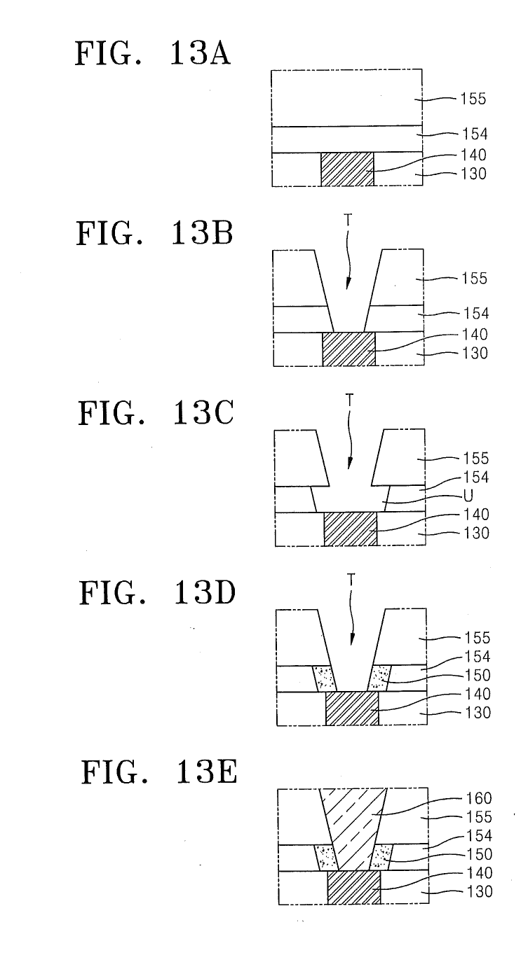

Layers, such as the first interlayer insulating layer 120, the first contact plug 122, the second interlayer insulating layer 130, the lower electrode 140, the stress relief buffer 150, the lower insulating layer 154, the upper insulating layer 155, the phase-change material region 160, the upper electrode 170, the second contact plug 180, the third interlayer insulating layer 182, and the upper wiring 190 described above, may be formed by using a sputtering process, a CVD process, a PECVD process, or an ALD process. Such layers may be flattened using etching and/or CMP. Operations for forming the stress relief buffer 150 and the phase-change material region 160 according to various embodiments will be described later with reference to FIGS. 13A through 13E.

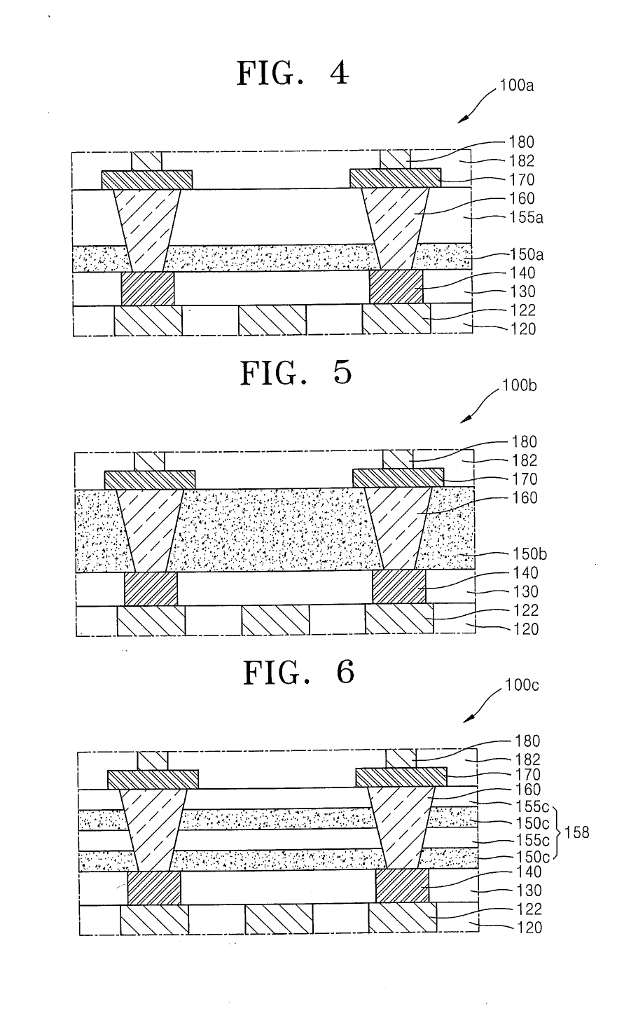

FIGS. 4 through 10 are cross-sectional views illustrating various phase-change non-volatile memory devices 100a, 100b, 100c, 100d, 100e, 200, and 200a according to some embodiments of the inventive subject matter. FIGS. 4 through 10 correspond to a region A of FIG. 3. Regarding the non-volatile memory devices 100a, 100b, 100c, 100d, 100e, 200, and 200a, descriptions about elements that are substantially identical or correspond to those in FIG. 3 will not be repeated.

Referring to FIG. 4, a non-volatile memory device 100a includes a stress relief layer 150a disposed on the second interlayer insulating layer 130, an upper insulating layer 155a disposed on the stress relief layer 150a. The stress relief layer 150a may be a contiguous layer surrounding the phase-change material region 160, for example, may be formed on the uppermost surface of the second interlayer insulating layer 130. Accordingly, at least a part, for example, a lower portion, of the phase-change material region 160 may be surrounded by the stress relief layer 150a. At least a part, for example, an upper portion, of the phase-change material region 160 may be surrounded by the upper insulating layer 155a. Comparing FIGS. 3 and 4, the non-volatile memory device 100a of FIG. 4 does not include the lower insulating layer 154. The upper insulating layer 155a may be formed from the same material forming the lower insulating layer 154 of FIG. 3.

Referring to FIG. 5, a non-volatile memory device 100b includes a stress relief layer 150b disposed on the second interlayer insulating layer 130. The stress relief layer 150b may be formed on the uppermost surface of the second interlayer insulating layer 130. The phase-change material region 160 may be surrounded by the stress relief layer 150b, e.g., the phase-change material region 160 may be buried in the stress relief layer 150b. The third interlayer insulating layer 182 is disposed on the stress relief layer 150b. Comparing FIGS. 3 and 5, the non-volatile memory device 100b of FIG. 5 does not include the lower insulating layer 154 and the upper insulating layer 155.

Referring to FIG. 6, a non-volatile memory device 100c may include a plurality of stress relief layers 150c in a multilayer structure 158. The multilayer structure 158 includes the plurality of stress relief layers 150c interleaved with a plurality of upper insulating layers 155c. The stress relief layer 150c may be formed on the uppermost surface of the second interlayer insulating layer 130. At least a part of the phase-change material region 160 may be surrounded by the stress relief layers 150c. In FIG. 6, two pairs of interleaved stress relief and upper insulating layers 150c, 155c are shown, but the number of such pairs is not so limited. Comparing FIGS. 3 and 6, the non-volatile memory device 100c of FIG. 6 does not include the lower insulating layer 154. The upper insulating layers 155c may include a material used in the lower insulating layer 154 of FIG. 3.

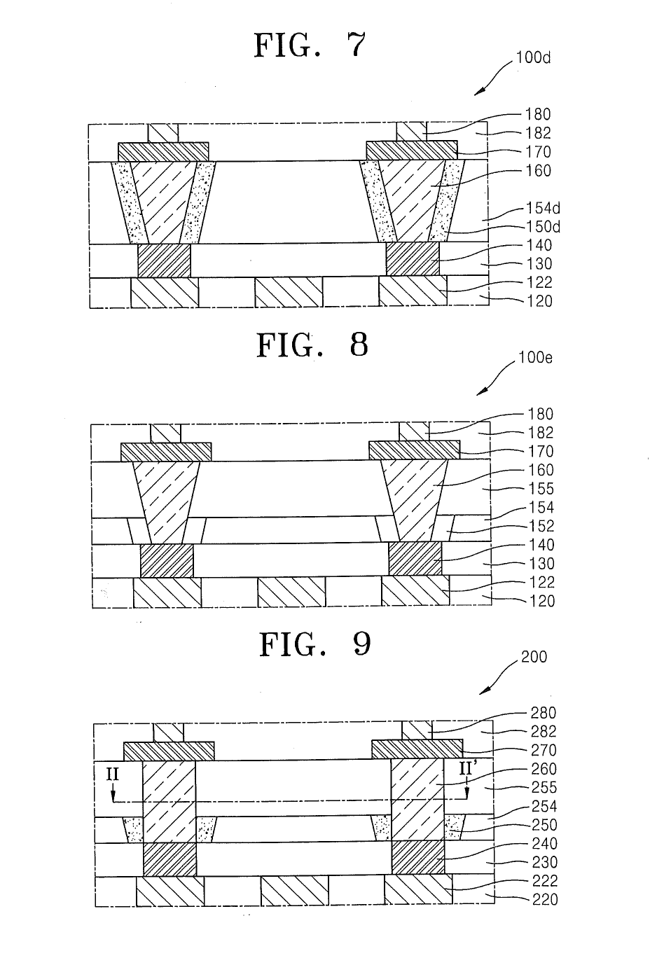

Referring to FIG. 7, a non-volatile memory device 100d includes a lower insulating layer 154d disposed on the second interlayer insulating layer 130 and a stress relief region 150c disposed on a sidewall of the phase-change material region 160. The phase-change material region 160 may be surrounded by the stress relief region 150c. The lower insulating layer 154d may contact a sidewall of the stress relief region 150c opposite the phase-change material region 160. Comparing FIGS. 3 and 7, the non-volatile memory device 100d of

FIG. 7 does not include the upper insulating layer 155. The lower insulating layer 154d may include a material used for the upper insulating layer 155 of FIG. 3. A shape of the stress relief region 150c illustrated in FIG. 7 is only an example, and embodiments of the inventive subject matter are not limited thereto.

Referring to FIG. 8, a non-volatile memory device 100e includes a lower insulating layer 154 disposed on a second interlayer insulating layer 130 and an upper insulating layer 155 disposed on the lower insulating layer 154. A stress relief void 152 (e.g. a gap filled with air or other gas) is disposed between the phase-change material region 160 and the lower insulating layer 154. At least a part, for example, a lower portion, of the phase-change material region 160 may be surrounded by the stress relief void 152. Specifically, the stress relief void 152 may surround a region, such as a memory region or a switching region, of the phase-change material region 160, wherein a crystallized state changes. Also, at least a part, for example, an upper portion, of the phase-change material region 160 may be surrounded by the upper insulating layer 155. The stress relief void 152 may absorb a stress energy generated by a crystallized state change of the phase-change material region 160.

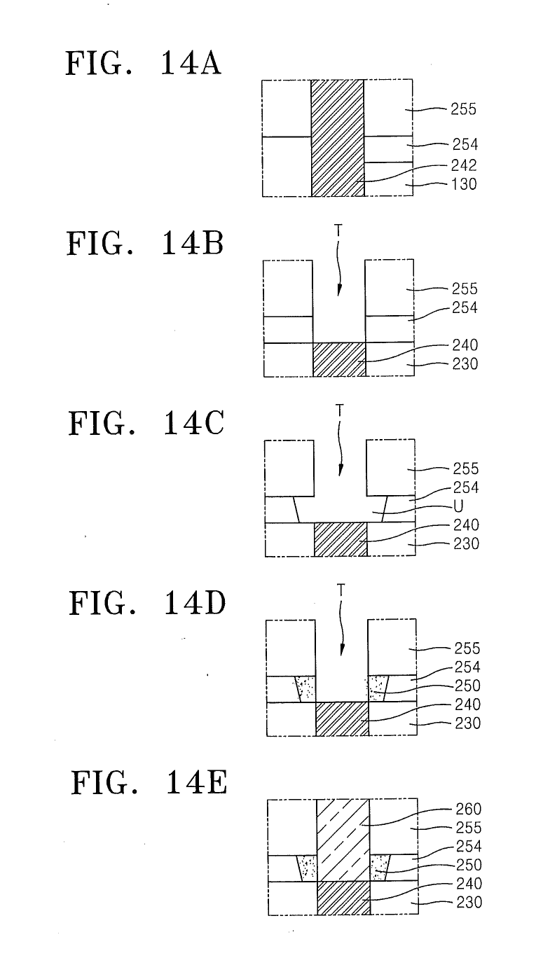

Referring to FIG. 9, a non-volatile memory device 200 includes a lower insulating layer 254 disposed on a second interlayer insulating layer 230, and an upper insulating layer 255 disposed on the lower insulating layer 254. At least a part, for example, a lower portion, of a phase-change material region 260 may be surrounded by a stress relief region 250. Specifically, the stress relief region 250 may surround a region, such as a memory region or a switching region, where phase change occurs in the phase-change material region 260. At least a part, for example, an upper portion, of the phase-change material region 260 may be surrounded by the upper insulating layer 255. In the illustrated embodiments, the stress relief region 250 may be disposed between the lower insulating layer 254 and the phase-change material region 260. An uppermost surface of the stress relief region 250 and an uppermost surface of the lower insulating layer 254 may be copular. Comparing FIGS. 3 and 9, a lower electrode 240 and the phase-change material region 260 in the embodiments of FIG. 9 may have the same width. Operations for forming the stress relief region 250 and the phase-change material region 260 will be described later with reference to FIG. 14.

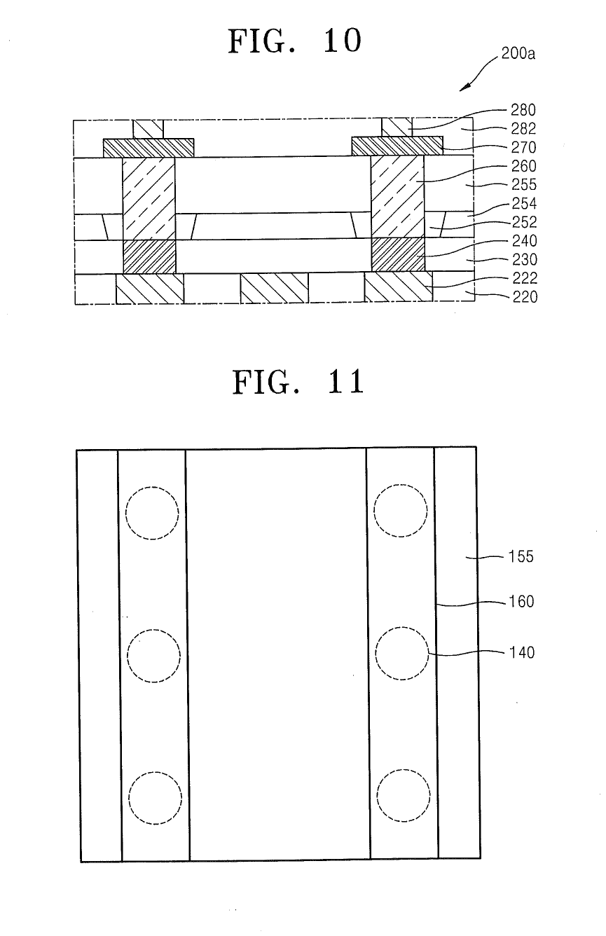

Referring to FIG. 10, a non-volatile memory device 200a includes a lower insulating layer 254 disposed on a second interlayer insulating layer 230, and an upper insulating layer 255 disposed on the lower insulating layer 254. A stress relief void 252 is disposed between the phase-change material region 260 and the lower insulating layer 254. At least a part, for example a lower portion, of the phase-change material region 260 may be surrounded by a stress relief void 252. Specifically, the stress relief void 252 may surround a region, such as a memory region or a switching region, of the phase-change material region 260, wherein a crystallized state changes. Also, at least a part, for example an upper portion, of the phase-change material region 260 may be surrounded by the upper insulating layer 255. The stress relief void 252 may absorb a stress energy generated due to a crystallized state change of the phase-change material region 260.

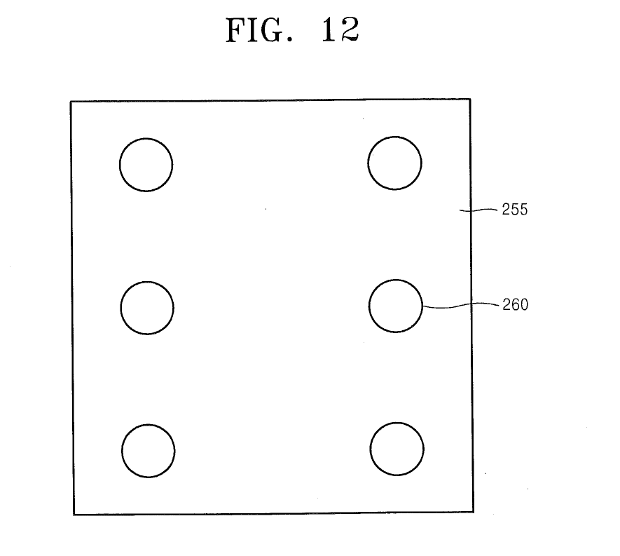

FIG. 11 is a plan view taken along a line I-I′ of FIG. 3, and FIG. 12 is a plan view taken along a line II-II′ of FIG. 9.

Referring to FIG. 11, a phase-change material region 160 has a linear shape extending along a first direction. A plurality of spaced-apart lower electrodes 140 is disposed below the phase-change material region 160. In FIG. 11, the lower electrodes 140 are illustrated in dotted lines. The lower electrode 140 may have a circular or a polygonal shape. Such a phase-change material region 160 may be used, for example, in the non-volatile memory devices 100a, 100b, 100c, 100d, and 100e of FIGS. 4 through 8. Operations for forming a stress relief buffer for the phase-change material region 160 will be described later with reference to FIGS. 13A through 13E.

Referring to FIG. 12, a phase-change material region 260 may comprise separate circular or polygonal shaped regions. Respective lower electrodes (refer electrodes 240 in FIG. 9) are disposed below the phase-change material regions 260. The phase-change material regions 260 may have the same width as the lower electrodes 240. Operations for forming a stress relief buffer for the phase-change material region 260 will be described later with reference to FIGS. 14A through 14E.

FIGS. 13A through 13E are cross-sectional views for describing operations for forming a stress relief buffer for the phase-change material region 160 of FIG. 3.

Referring to FIG. 13A, the lower insulating layer 154 and the upper insulating layer 155 are sequentially disposed on the second interlayer insulating layer 130 and the lower electrode 140 disposed in the second interlayer insulating layer 130.

Referring to FIG. 13B, parts of the lower insulating layer 154 and the upper insulating layer 155 are removed so as to form a trench T that penetrates the lower insulating layer 154 and the upper insulating layer 155 and exposes the lower electrode 140.

Referring to FIG. 13C, the lower insulating layer 154 is further removed so as to form an undercut recess U below the upper insulating layer 155. Because the lower insulating layer 154 and the upper insulating layer 155 have etch selectivity with respect to each other, the upper insulating layer 155 may not be removed.

Referring to FIG. 13D, a stress relief region 150 is formed in the undercut recess U. The stress relief region 150 may be formed by filing the undercut recess U using a process that is used to form a lining. Alternatively, the undercut recess U and the trench T may both be filled and material in the trench T may be removed to form the stress relief region 150. Referring to FIG. 13E, the phase-change material region 160 is formed by filling the trench T.

The operation performed in FIG. 13D may be omitted to form a stress relief void as described, for example, with reference to the stress relief void 152 shown in FIG. 8. Such a stress relief void may be formed by controlling process conditions in such a way that a material forming the phase-change material region 160 fills the trench T before the undercut recess U. The process conditions may increase a gap-filling rate of the phase-change material region 160 and deteriorate a gap-filling characteristic of the phase-change material region 160, such as a low deposition gas pressure, a low gas flow rate, or a high temperature. The operations described with reference to FIGS. 13A through 13E may be applied to the non-volatile memory devices 100a, 100b, 100c, 100d, and 100e of FIGS. 4 through 8.

FIGS. 14A through 14E are cross-sectional views illustrating operations for forming a stress relief buffer for the phase-change material region 260 of FIG. 9.

Referring to FIG. 14A, a conductive layer 242 is formed, penetrating the second interlayer insulating layer 230, the lower insulating layer 254, and the upper insulating layer 255.

Referring to FIG. 14B, a part of the conductive layer 242 is removed so as to form the lower electrode 240 having an uppermost surface at the same level as the uppermost surface of the second interlayer insulating layer 230. A trench T is formed through the lower insulating layer 254 and the upper insulating layer 255, exposing the lower electrode 240.

Referring to FIG. 14C, the lower insulating layer 254 is further removed so as to form an undercut recess U below the upper insulating layer 255. Because the lower insulating layer 254 and the upper insulating layer 255 have an etch selectivity with each other, the upper insulating layer 255 may not be removed.

Referring to FIG. 14D, a stress relief region 250 is formed by filling the undercut recess U. The stress relief region 250 may be formed by filling the undercut recess U using a process used to form a lining. Alternatively, the undercut recess U and the trench T may both be filled and material filling the trench T may be removed to form the stress relief region 250.

Referring to FIG. 14E, the phase-change material region 260 is formed by filling the trench T. Accordingly, the lower electrode 240 and the phase-change material region 260 may have the same width.

The operation performed in FIG. 14D may be omitted to form a stress relief void, such as the stress relief void 252 shown in FIG. 10. The stress relief void may be formed by controlling process conditions in such a way that a material forming the phase-change material region 260 fills the trench T before the undercut recess U. The process conditions may be conditions that increase a gap-filling rate of the phase-change material region 260 and deteriorate a gap-filling characteristic of the phase-change material region 260, such as a low deposition gas pressure, a low gas flow rate, or a high temperature. The operations described with reference to FIGS. 14A through 14E may be applied to the non-volatile memory device 200 of FIG. 9.

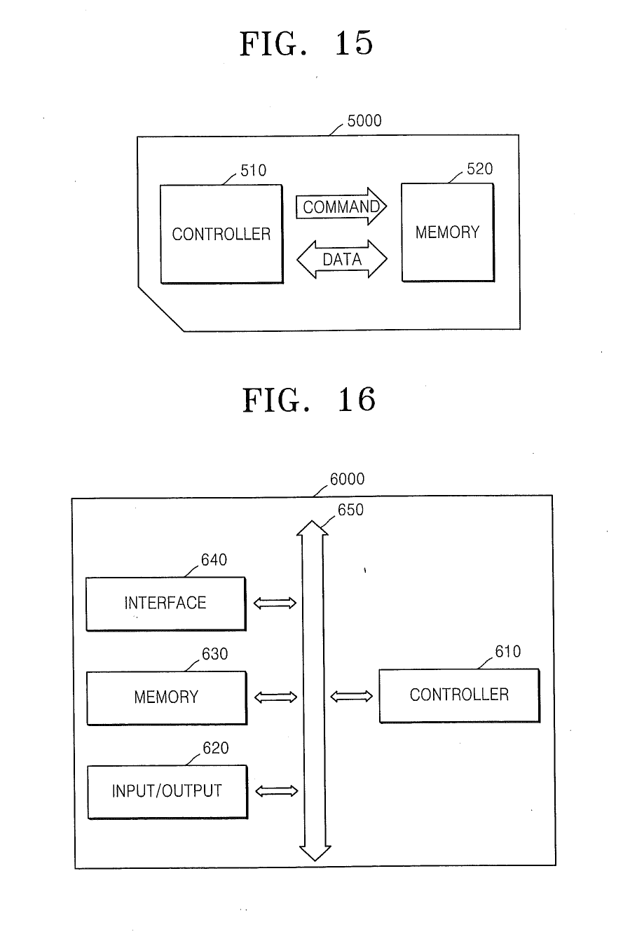

FIG. 15 is a schematic diagram illustrating a card 5000 according to some embodiments of the inventive subject matter.

Referring to FIG. 15, a controller 510 and a memory 520 may be disposed in the card 5000 so as to exchange an electrical signal. For example, when the controller 510 transmits a command, the memory 520 may transmit data. The memory 520 may include any one of the non-volatile memory array 1 and the non-volatile memory devices 100, 100a through 100e, 200, and 200a including a phase-change material, according to the embodiments described above. As well known in the related art, the non-volatile memory devices 100, 100a through 100e, 200, and 200a may be arranged in any shape of an architecture memory array (not shown) according to a corresponding logic gate design. A memory array arranged in a plurality of rows and columns may form at least one memory array bank (not shown). The memory 520 may include such a memory array (not shown) or a memory array bank (not shown). The card 5000 may further include a general row decoder (not shown), a column decoder (not shown), input/output (I/O) buffers (not shown), and/or a control register (not shown), so as to drive the memory array bank. The card 5000 may be any card, such as a memory stick card, a smart media (SM) card, a secure digital (SD), card, a mini SD card, or a multi media card (MMC), which may be used in a memory device.

FIG. 16 is a schematic diagram illustrating a system 6000 according to some embodiments of the inventive subject matter.

Referring to FIG. 16, the system 6000 may include a controller 610, an I/O device 620, a memory 630, and an interface 640. The system 6000 may be a mobile system or a system that transmits or receives information. The mobile system may be a personal digital assistant (PDA), a portable computer, a web tablet, a wireless phone, a mobile phone, a digital music player, or a memory card. The controller 610 may execute a program and control the system 6000. The controller 610 may be, for example, a microprocessor, a digital signal processor, a microcontroller, or a device similar thereto. The I/O device 620 may be used to input or output data of the system 6000. The system 6000 may be connected to an external device, such as a personal computer or a network, by using the I/O device 620 to exchange data with the external device. The I/O device 620 may be, for example, a keypad, a keyboard, or a display. The memory 630 may store code and/or data for operating the controller 610, and/or store data processed by the controller 610. The memory 630 may include any one of the non-volatile memory array 1 and the non-volatile memory devices 100, 100a through 100e, 200, and 200a including a phase-change material, according to the embodiments described above. The interface 640 may be a data transmission path between the system 6000 and the external device. The controller 610, the I/O device 620, the memory 630, and the interface 640 may communicate with each other through a bus 650. The system 6000 may be used in a mobile phone, an MP3 player, a navigation device, a portable multimedia player (PMP), a solid state disk (SSD), or household appliances.

The foregoing is illustrative of exemplary embodiments and is not to be construed as limiting the present invention. Although exemplary embodiments have been described, those of ordinary skill in the art will readily appreciate that many modifications are possible in the exemplary embodiments without materially departing from the novel teachings and advantages of the exemplary embodiments. Accordingly, all such modifications are intended to be included within the scope of the claims. Exemplary embodiments are defined by the following claims, with equivalents of the claims to be included therein.

1. A memory device comprising:
a substrate;
a memory cell comprising a first electrode on the substrate, a phase-change material region on the first electrode and a second electrode on the phase-change material region opposite the first electrode; and
a stress relief buffer adjacent a sidewall of the phase-change material region between the first and second electrodes.

2. The memory device of claim 1, wherein the stress relief buffer comprises a stress relief region contacting the sidewall of the phase-change material region.

3. The memory device of claim 2, wherein the stress relief region comprises silicon carbonitride (SiCN), boron carbonitride (BCN) and/or boron nitride (BN).

4. The memory device of claim 1, wherein the stress relief buffer comprises a void adjacent the sidewall of the phase-change material region.

5. The memory device of claim 1, wherein the stress relief buffer at least partially surrounds the phase-change material region.

6. The memory device of claim 1, further comprising an insulating layer disposed between the first and second electrodes and contacting the sidewall of the phase-change material layer.

7. The memory device of claim 6, wherein the stress relief buffer comprises a stress relief layer disposed on the insulating layer.

8. The memory device of claim 6, wherein the stress relief buffer comprises a plurality of stress relief layers interleaved with a plurality of insulating layers between the first and second electrodes.

9. The memory device of claim 1, further comprising an insulating layer disposed between the first and second electrodes and wherein the stress relief buffer is disposed between a sidewall of the insulating layer and the sidewall of the phase-change material region.

10. The memory device of claim 9, wherein the stress relief buffer comprises a stress relief region disposed between the sidewall of the insulating layer and the sidewall of the phase-change material region.

11. The memory device of claim 9, wherein the stress relief buffer comprises a void between the sidewall of the insulating layer and the sidewall of the phase-change material region.

12. The memory device of claim 1, wherein the stress relief buffer comprises a stress relief region extending between the first and second electrodes along the sidewall of the phase-change material region.

13. The memory device of claim 1, comprising a plurality of memory cells, each comprising a first electrode on the substrate, a phase-change material region on the first electrode and a second electrode on the phase-change material region opposite the first electrode, and wherein the stress relief buffer comprises a stress relief layer contacting sidewalls of the phase-change material layers of the plurality of memory cells.

14. The memory device of claim 1, comprising a plurality of memory cells, each comprising a first electrode on the substrate, a phase-change material region on the first electrode and a second electrode on the phase-change material region opposite the first electrode, and wherein the stress relief buffer comprises respective stress relief regions adjacent sidewalls of the phase-change material layers of respective ones of the plurality of memory cells.

15. A memory device comprising:
a first electrode;
a phase-change material region disposed on the first electrode;
a stress relief region surrounding at least a part of the phase-change material region; and
a second electrode disposed on the phase-change material region opposite the first electrode.

16. The memory device of claim 15, wherein the stress relief region surrounds a lower portion of the phase-change material region.

17. The memory device of claim 15, further comprising a lower insulating layer contacting a sidewall of the stress relief region opposite the phase-change material region.

18. The memory device of claim 17, wherein a surface of the stress relief region and an uppermost surface of the lower insulating layer are coplanar.

19.-22. (canceled)

23. The memory device of claim 15, wherein the stress relief region comprises a stress relief layer and wherein the phase-change material region is buried in the stress relief layer.

24.-32. (canceled)

33. A memory device comprising:
a first electrode;
a phase-change material region disposed on the first electrode;
a stress relief void surrounding at least a part of the phase-change material region; and
a second electrode disposed on the phase-change material region.

34. (canceled)
